(19) United States
(12) Patent Application Publication
(10) Pub. No.: US 2007/0293035 A1
(43) Pub. Date: Dec. 20, 2007

(54) Interlayer insulating layer and method of manufacturing the same

(75) Inventor: Yukinori Ikegawa, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED

(21) Appl. No.: 11/588,981

(22) Filed: Oct. 27, 2006

(30) Foreign Application Priority Data
Jun. 19, 2006 (JP) 2006-168410

(51) Int. Cl. H01L 21/4763

(52) U.S. Cl. 438/622

(57) ABSTRACT

When an insulating layer is patterned by etching, end surfaces of the insulating layer are perpendicularly formed. By doing so, for example, the diameter of a coil of a magnetic head can be reduced and in turn the magnetic head can be miniaturized. A method of manufacturing an interlayer insulating layer that electrically insulates two layers includes a step of forming insulating material layers on a base layer, a step of etching an uppermost insulating material layer out of the laminated insulating material layers into a predetermined pattern, and a step of etching the insulating material layer below the uppermost layer with the uppermost layer that has been etched into the pattern as an etching mask to form the interlayer insulating layer.

### BACKGROUND OF THE INVENTION

1. Field of the Invention

The present invention relates to an interlayer insulating layer and a method of manufacturing the same, such as an insulating layer that electrically insulates a recording coil and a base layer of a magnetic head, and to a method of manufacturing the same.

2. Related Art

FIG. 4 shows the construction of a read head 8 and a write head 10 of a magnetic head used in a magnetic disk apparatus. The read head 8 is equipped with a MR element 5 sandwiched between a lower shield layer 6 and an upper shield layer 7, and the write head 10 is equipped with a lower magnetic pole 12 and an upper magnetic pole 13 disposed on either side of a write gap 11.

A recording coil 14 is provided in the write head 10 by being wound around a back gap part 15 that connects a lower magnetic pole layer 16 and the upper magnetic pole 13. The lower magnetic pole 12, the lower magnetic pole layer 16, the back gap part 15, and the upper magnetic pole 13 form a magnetic circuit that produces a magnetic field across the write gap 11.

An insulating layer 18 that insulates the recording coil 14 from the lower magnetic pole layer 16 is provided between the recording coil 14 and the lower magnetic pole layer 16. An insulating material such as alumina, SiO₂, or the like is used for the insulating layer 18.

FIGS. 5A to 5D show the manufacturing steps up to the formation of the insulating layer 18 on the lower magnetic pole layer 16 and the formation of the recording coil 14. As shown in FIG. 5A, after alumina or SiO₂ has been sputtered onto the surface of the lower magnetic pole layer 16 to form the insulating layer 18, the part that is to be kept as the insulating layer 18 is covered with a resist 30. By carrying out dry etching with the insulating layer 18 covered by the resist 30, the insulating layer 18 is formed in a predetermined pattern on the surface of the lower magnetic pole layer 16 (see FIG. 5C).

FIG. 5D shows a state where a plating seed layer 32 has been formed on the surface of the substrate after the resist 30 has been removed, another resist has been patterned in accordance with a planar form of the recording coil 14, and then electroplating has been carried out with the plating seed layer 32 as the plating power supply layer to form the recording coil 14.

By removing exposed parts of the plating seed layer 32 from the state shown in FIG. 5D by ion milling or the like, the recording coil 14 is formed in a discrete pattern. Next, by carrying out electroplating, the lower magnetic pole 12 and the back gap part 15 can be formed in predetermined patterns.

### Patent Document 1

Japanese Laid-Open Patent Publication No. 2004-152470

### Patent Document 2

Japanese Laid-Open Patent Publication No. H07-272215

### SUMMARY OF THE INVENTION

In the manufacturing process shown in FIG. 5, the method of etching the insulating layer 18 to form a predetermined pattern differs according to the material used as the insulating layer 18. For example, when the insulating layer 18 is made of alumina, dry etching such as ion milling is used with the resist 30 as a mask. When the insulating layer 18 is made of SiO₂, chemical reactive etching such as RIE (Reactive Ion Etching) is carried out with the resist 30 as a mask.

In either case, when the insulating layer 18 is etched, the end surfaces of the insulating layer 18 become tapered (see FIG. 5C). This is because when the insulating layer 18 is etched, the etching rate of the resist 30 is faster than the etching rate of the insulating layer 18, which makes it necessary to form the resist 30 thicker (i.e., around five times thicker) than the insulating layer 18, resulting in deterioration in the perpendicularity of the etching end surfaces due to the insulating layer 18 being shielded by the resist 30. Such phenomenon is also caused by positions close to the side surfaces of the resist 30 being more difficult to etch compared to positions that are distant from the side surfaces.

If the end surfaces of the insulating layer 18 become tapered (“skirt-shaped”) in this way, the recording coil 14 will become disposed at a distance from the edge of the insulating layer 18, which makes it difficult to reduce the diameter of the recording coil 14. Also, since the extent to which the gap between (i) the lower magnetic pole 12 and the back gap part 15 and (ii) the recording coil 14 can be reduced is restricted, miniaturization of the magnetic head is also restricted.

As the recording density of magnetic disk apparatuses has increased, the size of the magnetic head has also been reduced. In reality, it is no longer possible to ignore the tapering of the end surfaces of the insulating layer 18 since it makes it difficult to reduce the diameter of the recording coil 14 and to miniaturize the magnetic head.

Note that it might be possible to overlook the tapering of the end surfaces of the insulating layer 18, form the planar dimensions of the resist 30 that forms the insulating layer 18 slightly smaller than the predetermined shape, and thereby form the outer edge of the tapered surface with the predetermined dimensions when the insulating layer 18 is etched. However, in such case, when the recording coil 14 has been formed on the insulating layer 18, if part of the recording coil 14 is positioned at the edge of the insulating layer 18, there is the problem of a fall in the reliability of the product.

The present invention was conceived to solve the problem described above and it is an object of the present invention to provide an interlayer insulating layer where the edge surfaces of the insulating layer can be made perpendicular when patterning the insulating layer by etching and thereby makes it possible to reduce the diameter of a recording coil of a magnetic head and to miniaturize the magnetic head, for example. It is another object of the present invention to provide a method of manufacturing such interlayer insulating layer.

To achieve the stated object, an interlayer insulating layer according to the present invention electrically insulates two layers and is formed by laminating a plurality of insulating material layers composed of different insulating materials, wherein an uppermost of the insulating material layers has a slower etching rate compared to insulating layers therebelow.

Also, by forming the uppermost of the insulating material layers thinner than a combined thickness of the insulating material layers therebelow, it is possible to form the end surfaces of the insulating material layers therebelow in distinct shapes in accordance with the end surface shapes of the uppermost layer.

As the interlayer insulating layer, it is effective to use an insulating layer formed with a double-layer construction where a first insulating material layer made of SiO₂ and a second insulating material layer made of alumina are laminated in that order on a base layer.

A magnetic head according to the present invention includes a base layer; a recording coil, and an interlayer insulating layer that insulates the base layer and the recording coil, wherein the interlayer insulating layer is formed by laminating a plurality of insulating material layers composed of different insulating materials.

An uppermost of the insulating material layers may have a slower etching rate compared to insulating material layers therebelow.

A method of manufacturing according to the present invention manufactures an interlayer insulating layer that electrically insulates two layers and includes: a step of forming a plurality of layers including at least one insulating material layer; a step of etching an uppermost layer out of the plurality of layers into a predetermined pattern; and a step of etching at least one insulating material layer below the uppermost layer with the uppermost layer that has been etched into the predetermined pattern as an etching mask.

In the step of forming the plurality of layers, the uppermost layer may be formed with a thinner thickness than a combined thickness of the at least one insulating layer therebelow.

Also, by selecting a material with an etching rate of no greater than 1/10 of the etching rate of the at least one insulating layer therebelow as the material of the uppermost layer, it becomes possible to form the uppermost insulating material layer thinner than the entire thickness of the at least one insulating layer therebelow, and to form the etching end surfaces of the interlayer insulating layer as perpendicular surfaces.

It is effective to form the interlayer insulating layer with a double-layer construction including a first insulating material layer made of SiO₂ and a second insulating material layer made of alumina.

A metal film may be formed as the uppermost layer, the metal film may be etched into a predetermined pattern, and the at least one insulating material layer below the metal film may be etched with the uppermost layer that has been etched into the predetermined pattern as an etching mask. By doing so, the at least one insulating material layer can be patterned into a predetermined pattern.

It is also effective for the metal film to be made of one material selected from Cr, NiFe, Ru, Au, and Pt.

With the interlayer insulating layer and the method of manufacturing the same according to the present invention, by using the uppermost layer of a plurality of laminated layers as an etching mask for etching the insulating material layers therebelow, it is possible to form the etching end surfaces of the insulating material layers as perpendicular surfaces. It is therefore possible to form the coil of a magnetic head, for example, on the interlayer insulating layer with high precision. Since the etching rate of the uppermost insulating material layer is slower than that of the insulating material layers therebelow, the uppermost insulating material layer can be effectively used as an etching mask when patterning the insulating material layers below the uppermost layer.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIG. 1 is a cross-sectional view showing the construction of a magnetic head that includes an interlayer insulating layer according to the present invention;

FIGS. 2A to 2E are diagrams useful in explaining processes that form the interlayer insulating layer;

FIG. 3 is a plan view of a magnetic disk apparatus;

FIG. 4 is a cross-sectional view showing the construction of the magnetic head; and

FIGS. 5A to 5D are diagrams useful in explaining the conventional method of forming an insulating layer in a pattern.

### DESCRIPTION OF THE PREFERRED EMBODIMENTS

Preferred embodiments of the present invention will now be described in detail with reference to the attached drawings.

### Construction of a Magnetic Head

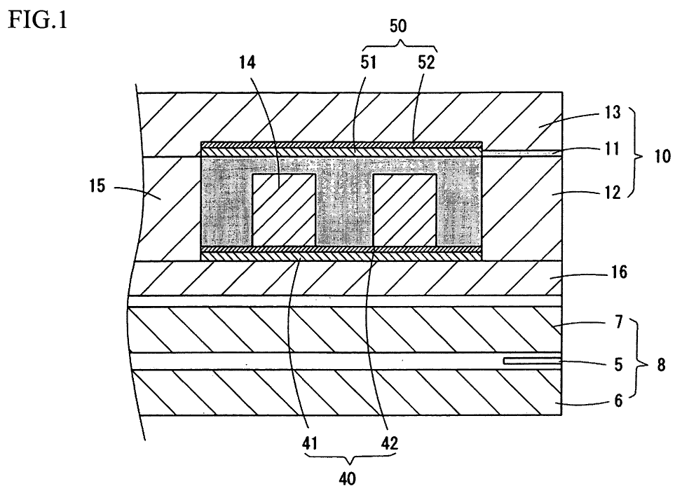

FIG. 1 is a cross-sectional view showing the construction of embodiments of an interlayer insulating layer and a magnetic head formed by applying a method of manufacturing the interlayer insulating layer. The constructions of the read head 8 and the write head 10 of the magnetic head according to the present embodiment are the same as those of the conventional magnetic head shown in FIG. 4. The magnetic head according to the present embodiment is characterized by the construction of an insulating layer 40 that electrically insulates the lower magnetic pole layer 16 and the recording coil 14.

As shown in FIG. 4, in the conventional magnetic head, the insulating layer 18 that electrically insulates the lower magnetic pole layer 16 and the recording coil 14 is formed of a single layer composed of an insulating material such as alumina or SiO₂. On the other hand, in the magnetic head according to the present embodiment, the insulating layer 40 that electrically insulates the recording coil 14 and the lower magnetic pole layer 16 is formed with a double-layer construction composed of a first insulating material layer 41 and a second insulating material layer 42 composed of different insulating materials.

The insulating layer 40 is formed with a double layer construction so that the second insulating material layer 42 formed on the first insulating material layer 41 can be used as an etching mask when patterning the first insulating material layer 41 by etching.

To etch the first insulating material layer 41 with the second insulating material layer 42 as an etching mask, insulating materials with different etching rates during the etching operation that etches the first insulating material layer 41 are used as the first insulating material layer 41 and the second insulating material layer 42. Since the second insulating material layer 42 is used as an etching mask when etching the first insulating material layer 41, the insulating material of the second insulating material layer 42 has a slower etching rate than the insulating material of the first insulating material layer 41 (i.e., the material of the second insulating material layer 42 is more difficult to etch).

The thicknesses of the first insulating material layer 41 and the second insulating material layer 42 can be set as appropriate, but since the second insulating material layer 42 is used as the etching mask, the thickness of the second insulating material layer 42 should be set thinner than the first insulating material layer 41.

By making the second insulating material layer 42 sufficiently thin, it is possible to form the first insulating material layer 41 in a pattern with the second insulating material layer 42 as an etching mask and to make the etching end surfaces of the first insulating material layer 41 perpendicular to the surface of the lower magnetic pole layer 16 without becoming tapered.

If it is possible to form the end surfaces of the first insulating material layer 41 as perpendicular surfaces, when the recording coil 14 is formed on the insulating layer 40, it will be possible to dispose the recording coil 14 close to the end surfaces of the insulating layer 40 and to narrow the gap between the recording coil 14 and the magnetic pole, thereby making it possible to reduce the diameter of the recording coil 14 and in turn to miniaturize the magnetic head. By forming the recording coil 14 with a small diameter, it is possible to reduce the inductance of the coil and thereby improve the high-frequency characteristics of the magnetic head.

Although the gaps between windings of the recording coil 14, the gap between the recording coil 14 and the lower magnetic pole 12, and the gap between the recording coil 14 and the back gap part 15 have been drawn comparatively wide in FIG. 4, the gaps between windings of the recording coil 14, the gap between the recording coil 14 and the lower magnetic pole 12, and the gap between the recording coil 14 and the back gap part 15 are extremely narrow at 1 μm or below. Accordingly, forming the end surfaces of the insulating layer 40 perpendicularly effectively contributes to miniaturization of the recording coil 14 and to miniaturization of the magnetic head.

Note that the two layer construction of the insulating layer 40 can also be used for an insulating layer 50 that electrically insulates the recording coil 14 and the upper magnetic pole 13. In the same way as the insulating layer 40, the insulating layer 50 is constructed of a first insulating material layer 51 and a second insulating material layer 52. The first insulating material layer 51 and the second insulating material layer 52 have the same constructions as the first insulating material layer 41 and the second insulating material layer 42 described above.

As described earlier, the first insulating material layer 41 and the second insulating material layer 42 are determined with consideration to the etching rate when patterning the insulating layer 40. Accordingly, appropriate materials should be selected as the insulating materials used in the first insulating material layer 41 and the second insulating material layer 42. In the magnetic head according to the present embodiment, SiO₂ is used as the insulating material of the first insulating material layer 41 and alumina is used as the insulating material of the second insulating material layer 42. RIE (Reactive Ion Etching) is used when etching an insulating layer composed of SiO₂, and since the etching rate during RIE of alumina is slower (around 1/100) than that of SiO₂, the second insulating material layer 42 is effective as an etching mask when patterning the first insulating material layer 41 using RIE.

Although the insulating layer 40 has a double-layer construction composed of the first insulating material layer 41 and the second insulating material layer 42 in the present embodiment, the insulating layer 40 may be constructed of three or more layers, with the uppermost insulating layer being used as an etching mask for the insulating layers below.

### Method of Forming the Interlayer Insulating Layer

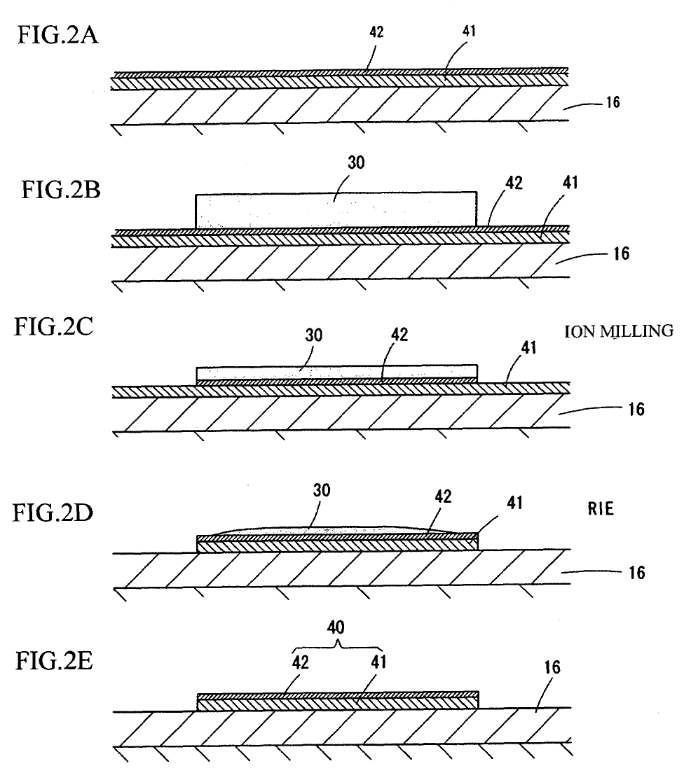

FIGS. 2A to 2E show an embodiment of the process for forming the insulating layer 40 on the surface of the lower magnetic pole layer 16 as an interlayer insulating layer for electrically insulating the recording coil 14 and the lower magnetic pole layer 16 as part of the manufacturing process of a magnetic head. FIG. 2A shows a state where the first insulating material layer 41 and the second insulating material layer 42 have been formed so as to cover the surface of the lower magnetic pole layer 16.

In reality, a Si0₂ film that constructs the first insulating material layer 41 is formed on the surface of a substrate (work) on which the lower magnetic pole layer 16 has been formed and then an alumina film that constructs the second insulating material layer 42 is formed. Here, the first insulating material layer 41 made of SiO₂ is 300 nm thick and the second insulating material layer 42 made of alumina is 50 nm thick.

Next, the surface of the second insulating material layer 42 is covered with the resist 30 which is then exposed and developed to pattern the resist 30 so as to cover the parts that are to be kept and used as the insulating layer 40 (see FIG. 2B). The thickness of the resist 30 may be set at the thickness required to etch the second insulating material layer 42, that is, to etch the alumina. The alumina is etched by ion milling. Since the second insulating material layer 42 is around 50 nm thick, the resist 30 should be around 500 nm thick.

FIG. 2C shows a state where the second insulating material layer 42 has been etched by ion milling with the resist 30 as a mask. The ion milling is stopped when the second insulating material layer 42 has been etched to produce the desired pattern in the second insulating material layer 42. Due to the ion milling, the resist 30 is also etched and becomes thinner.

FIG. 2D shows a state where the first insulating material layer 41 has been etched by RIE (Reactive Ion Etching) that uses an etching gas such as CF₄. In this etching operation, the resist 30 remaining on the surface of the second insulating material layer 42 effectively does not contribute to the etching of the first insulating material layer 41 and it is the second insulating material layer 42 that acts as the etching mask when patterning the first insulating material layer 41.

As described earlier, the alumina that composes the second insulating material layer 42 has a slower (around 1/100 or below) etching rate during RIE than the SiO₂ that composes the first insulating material layer 41 and therefore is effective as an etching mask when patterning the first insulating material layer 41.

Since the second insulating material layer 42 is thin compared to the first insulating material layer 41, the shielding action due to the thickness of the etching mask can be ignored so that the etching end surfaces of the first insulating material layer 41 are formed perpendicular to the surface of the lower magnetic pole layer 16.

FIG. 2E shows a state where the resist 30 remaining on the surface of the second insulating material layer 42 after the patterning of the first insulating material layer 41 has been removed to form the insulating layer 40 composed of the first insulating material layer 41 and the second insulating material layer 42.

Note that a process that removes the resist 30 remaining on the surface of the second insulating material layer 42 may be carried out after the second insulating material layer 42 has been patterned by ion milling so that when the first insulating material layer 41 is etched by RIE, the first insulating material layer 41 is etched in a state where only the second insulating material layer 42 remains on the first insulating material layer 41.

By doing so, the insulating layer 40 is formed in a predetermined pattern on the surface of the lower magnetic pole layer 16. The insulating layer 40 is formed with end surfaces that are perpendicular to the surface of the lower magnetic pole layer 16 and the edges of the insulating layer 40 are clearly formed without becoming skirt-shaped. When the recording coil 14 is formed in accordance with the position of the insulating layer 40, the entire surface of the insulating layer 40 can be used as the region for forming the recording coil 14 and therefore the recording coil 14 can be formed with high precision.

Note that although the first insulating material layer 41 is formed of SiO₂ and the second insulating material layer 42 is formed of alumina in the present embodiment, the insulating materials that compose the respective insulating layers are not limited to such materials and a suitable combination of materials can be selected with consideration to the etching rates thereof during the etching operation.

The thicknesses of the first insulating material layer 41 and the second insulating material layer 42 can also be set with consideration to the etching rates. If the etching rate of the second insulating material layer 42 when etching the first insulating material layer 41 is around 1/10 or below of the etching rate of the first insulating material layer 41, it will be possible to set the thickness of the second insulating material layer 42 sufficiently thinly compared to the thickness of the first insulating material layer 41. It will therefore be possible to use the second insulating material layer 42 effectively as an etching mask for patterning the first insulating material layer 41 by etching.

From the ratio of the etching rates of the first insulating material layer 41 and the second insulating material layer 42, in practical use the second insulating material layer 42 should have a thickness of around 5 nm or higher. It should also be obvious that the second insulating material 42 may be formed fairly thickly. However, if the second insulating material layer 42 is formed thickly, more time will be taken to etch the second insulating material layer 42, which lowers the overall manufacturing efficiency. Even when thickly formed, the insulating layer 40 that electrically insulates the lower magnetic pole layer 16 and the recording coil 14 is around 0.4 μm thick. Accordingly, the thickness of the second insulating material layer 42 should be around 0.1 μm or below.

Although the insulating layer 40 has a double-layer construction composed of the first insulating material layer 41 and the second insulating material layer 42 in the present embodiment, the insulating layer 40 may be constructed of three or more layers. In this case also, by using the uppermost insulating layer constructing the insulating layer 40 as an etching mask for etching the insulating layers below, it is possible to form the etching end surfaces of the insulating layer 40 as perpendicular surfaces.

In the present embodiment, by providing the second insulating material layer 42 made of alumina as the uppermost layer of the insulating layer 40, there is also the advantage that it is possible to improve the attachment between the insulating layer 40 and the recording coil 14 formed on the insulating layer 40. With SiO₂, the attachment force for a coil or wiring pattern is weak, so that if a coil or wiring pattern is formed on the surface of the SiO₂, there can be the problem of the coil or wiring pattern becoming detached. For this reason, to improve the reliability of the magnetic head, it is effective to form the surface of the insulating layer 40 with the second insulating material layer 42 made of alumina to which a coil or wiring pattern is favorably attached.

Note that although the insulating layer 40 is constructed with both the first insulating material layer 41 and the second insulating material layer 42 formed of insulating materials in the present embodiment, the second insulating material layer 42 only needs to function as an etching mask for the first insulating material layer 41 and therefore does not need to be formed of an insulating material.

For example, in place of an insulating material, a metal film of Cr, NiFe, Ru, Au, Pt, or the like can be used in place of the second insulating material layer 42. If, like the listed metals, the etching rate during RIE is slower than the etching rate of the first insulating material layer 41, it will be possible to use the metal film as an etching mask when etching the first insulating material layer 41. Since the first insulating material layer 41 composes the main part of the insulating layer 40, using a metal film in place of the second insulating material layer 42 is not problematic for the electrical insulating characteristics of the insulating layer 40. However, when a metal film is used in place of the second insulating material layer 42, after the recording coil 14 has been patterned, unnecessary parts of the metal film on the first insulating material layer 41 need to be removed by ion milling or the like to prevent the recording coil 14 from being electrically shorted by the metal film.

After the lower magnetic pole 12 and the back gap part 15, and then the upper magnetic pole 13 of the magnetic head shown in FIG. 1 have been formed on the insulating layer 40 according to the method described earlier, it is possible to form a plating seed layer on the surface of the substrate (i.e., the work), to form a resist that forms the lower magnetic pole 12 and the back gap part 15 in a pattern on the surface of the plating seed layer, and then to build up the lower magnetic pole 12 and the back gap part 15 by electroplating. These manufacturing processes are the same as the manufacturing processes of the conventional magnetic head.

Note that the method of etching an insulating layer to form a predetermined pattern described above is not limited to forming the insulating layer 40 provided between the lower magnetic pole layer 16 and the recording coil 14 of a magnetic head, and it is possible to use the method as a general method of forming an insulating layer in a predetermined pattern on the surface of a base layer.

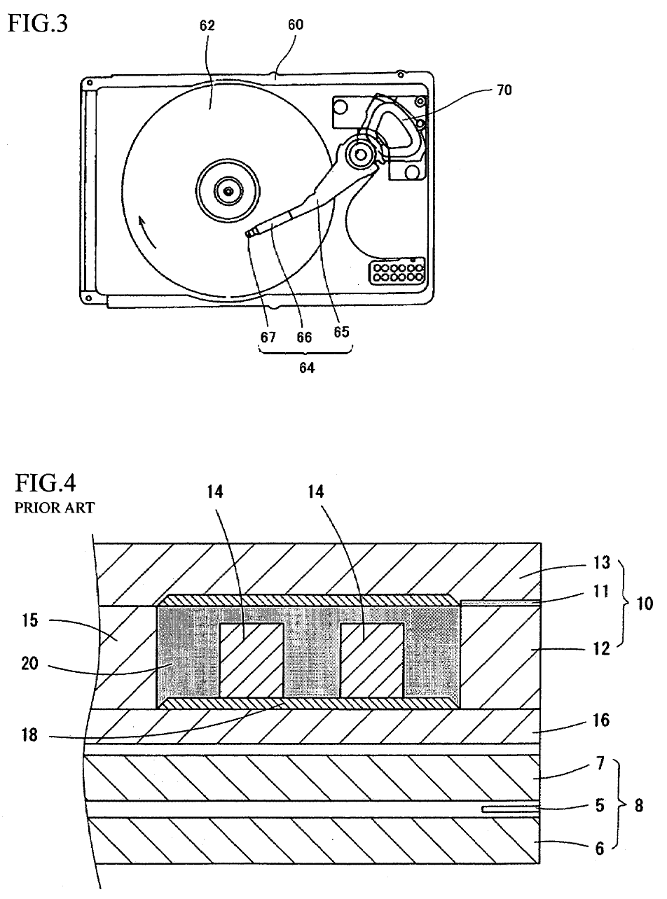

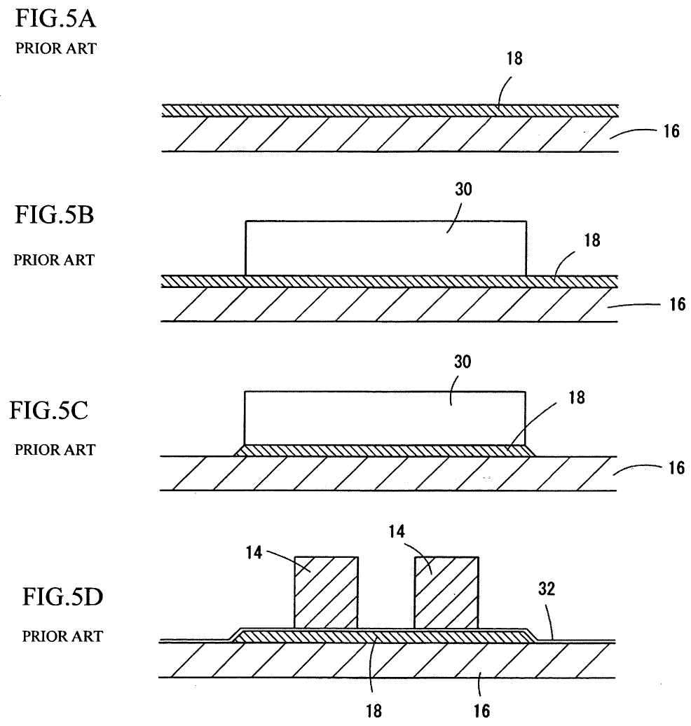

FIG. 3 shows an example of a magnetic disk apparatus equipped with a magnetic head. This magnetic disk apparatus has a recording medium 62 mounted inside a casing 60 formed in a box-like shape, and includes a rotation mechanism for the recording medium 62, a carriage assembly 64, and an actuator 70 for causing the carriage assembly 64 to carry out a seek operation. In the carriage assembly 64, a suspension 66 is attached to a carriage arm 65, and a slider 67 on which the magnetic head according to the present invention is formed is mounted on the end of the suspension 66.

In this magnetic disk apparatus, information is recorded on the recording medium 62 by the write head 10 of the magnetic head formed on the slider 67 and information recorded on the recording medium 62 is reproduced by the read head 8 of the magnetic head.

What is claimed is:

1. An interlayer insulating layer that electrically insulates two layers and is formed by laminating a plurality of insulating material layers composed of different insulating materials, wherein an uppermost of the insulating material layers has a slower etching rate compared to insulating layers therebelow.

2. An interlayer insulating layer according to claim 1, wherein the uppermost of the insulating material layers is formed with a thinner thickness than a combined thickness of the insulating material layers therebelow.

3. An interlayer insulating layer according to claim 1, wherein the interlayer insulating layer is formed with a double-layer construction where a first insulating material layer made of SiO₂ and a second insulating material layer made of alumina are laminated in that order on a base layer.

4. A magnetic head comprising:
a base layer;
a recording coil; and
an interlayer insulating layer that insulates the base layer and the recording coil,
wherein the interlayer insulating layer is formed by laminating a plurality of insulating material layers composed of different insulating materials.

5. A magnetic head according to claim 4, wherein an uppermost of the insulating material layers has a slower etching rate compared to insulating material layers therebelow.

6. A method of manufacturing an interlayer insulating layer that electrically insulates two layers, comprising:
a step of forming a plurality of layers including at least one insulating material layer;
a step of etching an uppermost layer out of the plurality of layers into a predetermined pattern; and
a step of etching at least one insulating material layer below the uppermost layer with the uppermost layer that has been etched into the predetermined pattern as an etching mask.

7. A method of manufacturing an interlayer insulating layer according to claim 6, wherein in the step of forming the plurality of layers, the uppermost layer is formed with a thinner thickness than a combined thickness of the at least one insulating layer therebelow.

8. A method of manufacturing an interlayer insulating layer according to claim 7, wherein a material with an etching rate of no greater than 1/10 of the etching rate of the at least one insulating layer therebelow is used as the material of the uppermost layer.

9. A method of manufacturing an interlayer insulating layer according to claim 6, wherein the interlayer insulating layer is formed with a double-layer construction including a first insulating material layer made of SiO₂ and a second insulating material layer made of alumina.

10. A method of manufacturing an interlayer insulating layer according to claim 6, wherein a metal film is formed as the uppermost layer, the metal film is etched into a predetermined pattern, and the at least one insulating material layer below the metal film is etched with the uppermost layer that has been etched into the predetermined pattern as an etching mask.

11. A method of manufacturing an interlayer insulating layer according to claim 10, wherein the metal film is made up of one material selected from Cr, NiFe, Ru, Au, and Pt.
